(19) United States
(12) Patent Application Publication
(10) Pub. No.: US 2023/0234183 A1
(43) Pub. Date: Jul. 27, 2023

(54) METHOD OF PROCESSING WORKPIECE

(71) Applicant: DISCO CORPORATION, Tokyo (JP)

(72) Inventor: Daichi SHUTO, Tokyo (JP)

(73) Assignee: DISCO CORPORATION, Tokyo (JP)

(21) Appl. No.: 18/149,897

(22) Filed: Jan. 4, 2023

(30) Foreign Application Priority Data
Jan. 25, 2022 (JP) 2022-009249

(51) Int. Cl. B24B 47/10; B24B 7/04; B24B 7/22

(52) U.S. Cl. CPC B24B 47/10; B24B 7/04; B24B 7/228

(57) ABSTRACT

A method of processing a workpiece having electrodes embedded therein includes a holding step of holding a face side of the workpiece on a chuck table, a grinding step of, after the holding step, bringing grindstones of a grinding wheel into contact with a reverse side of the workpiece held on the chuck table while rotating the grinding wheel in a first direction, thereby grinding the workpiece until the electrodes are exposed on the reverse side of the workpiece, and an electrode processing step of, after the grinding step, processing the electrodes by bringing the grindstones into contact with the electrodes exposed on the reverse side of the workpiece held on the chuck table while rotating the grinding wheel in a second direction opposite the first direction.

### BACKGROUND OF THE INVENTION

### Field of the Invention

The present invention relates to a method of processing a workpiece having electrodes embedded therein.

### Description of the Related Art

A process of manufacturing device chips uses as workpieces wafers each having a plurality of devices constructed in respective areas demarcated on its face side by a plurality of intersecting streets or projected dicing lines. In the manufacturing process, such a wafer is divided along the streets to produce a plurality of device chips that include the respective devices. The produced device chips will be incorporated into various electronic appliances such as cellular phones and personal computers. Recent years have seen a practically established technology for manufacturing device chips each including a plurality of stacked devices, i.e., stacked device chips, for high integration purposes. For example, a stacked device chip is fabricated by stacking a plurality of devices together and electrically interconnecting the devices with through electrodes (TSVs: through-silicon vias) that extend perpendicularly through the device chips. Since the through electrodes can make the interconnects interconnecting the devices shorter than bonded wires, the through electrodes are effective in reducing the size of stacked device chips and increasing their signal processing speed.

For manufacturing stacked device chips in which stacked devices are electrically interconnected by through electrodes, it has been customary to use stacked wafers having through electrodes as workpieces to be processed (see, for example, Japanese Patent Laid-open No. 2001-53218). For example, a plurality of wafers with through electrodes are stacked together, and the devices included in the wafers are electrically interconnected by the through electrodes, thereby producing a stacked wafer. The stacked wafer is divided along streets to fabricate a plurality of stacked device chips.

### SUMMARY OF THE INVENTION

For constructing through electrodes in a workpiece such as a wafer, first, grooves defined in a face side of the workpiece are filled with an electrically conductive material, providing electrodes embedded in the workpiece. Then, the workpiece is ground on its reverse side to expose the electrodes on the reverse side. The electrodes embedded in the wafer and having opposite ends exposed on the face and reverse sides act as through electrodes extending thicknesswise through the workpiece.

A grinding apparatus is used to grind workpieces. The grinding apparatus includes a chuck table for holding a workpiece thereon and a grinding unit for grinding the workpiece on the chuck table. A grinding wheel including a plurality of grindstones is mounted on the grinding unit. The workpiece is held on the chuck table and then the grindstones are brought into abrasive contact with the reverse side of the workpiece while the chuck table and the grinding wheel are being rotated relatively to each other about their respective central axes, thereby grinding the reverse side of the workpiece.

When the grindstones grind the reverse side of the workpiece until the embedded electrodes in the workpiece are exposed on the reverse side of the workpiece, the grindstones tend to contact the embedded electrodes exposed on the reverse side of the workpiece. Upon contact with the electrodes, the grindstones that are being rotated at a high speed are likely to elongate part of the electrodes into hair-like burrs. The burrs may cause the electrodes to be shaped irregularly on the reverse side of the workpiece and develop problems such as short circuits between adjacent ones of the electrodes, and may hence be responsible for reductions in the quality of the device chips.

The present invention has been made in view of the above drawbacks. It is an object of the present invention to provide a method of processing a workpiece while preventing burrs from remaining as they are thereon.

In accordance with an aspect of the present invention, there is provided a method of processing a workpiece having electrodes embedded therein, including a holding step of holding a face side of the workpiece on a chuck table, a grinding step of, after the holding step, bringing grindstones of a grinding wheel into contact with a reverse side of the workpiece held on the chuck table while rotating the grinding wheel in a first direction, thereby grinding the workpiece until the electrodes are exposed on the reverse side of the workpiece, and an electrode processing step of, after the grinding step, processing the electrodes by bringing the grindstones into contact with the electrodes exposed on the reverse side of the workpiece held on the chuck table while rotating the grinding wheel in a second direction opposite the first direction.

In the method of processing a workpiece according to the aspect of the present invention, after the grinding wheel that is being rotated in the first direction has ground the workpiece to expose the electrodes on the reverse side of the workpiece, the grinding wheel that is being rotated in the second direction opposite the first direction processes the electrodes to reduce or remove the burrs extending from the electrodes, so that the burrs are prevented from remaining as they are on the workpiece after it has been ground.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view of a workpiece;

FIG. 1B is a fragmentary cross-sectional view of the workpiece;

FIG. 1C is a perspective view of a device on the workpiece;

FIG. 2 is a perspective view of a grinding apparatus;

FIG. 3 is a cross-sectional view of a chuck table of the grinding apparatus;

FIG. 4 is a flowchart of a method of processing a workpiece according to an embodiment of the present invention;

FIG. 5 is a perspective view of the grinding apparatus in which the workpiece is held on the chuck table thereof;

FIG. 6A is a side-elevational view of the grinding apparatus, illustrating a manner in which the grinding apparatus is grinding the workpiece;

FIG. 6B is a side-elevational view of the grinding apparatus, illustrating a manner in which grindstones are spaced from the workpiece;

FIG. 6C is a side-elevational view of the grinding apparatus, illustrating a manner in which the grinding apparatus is processing electrodes;

FIG. 7A is a plan view of the workpiece in a grinding step;

FIG. 7B is a plan view of electrodes in the grinding step;

FIG. 8A is a plan view of the workpiece in an electrode processing step; and

FIG. 8B is a plan view of the electrodes in the electrode processing step.

### DETAILED DESCRIPTION OF THE PREFERRED EMBODIMENT

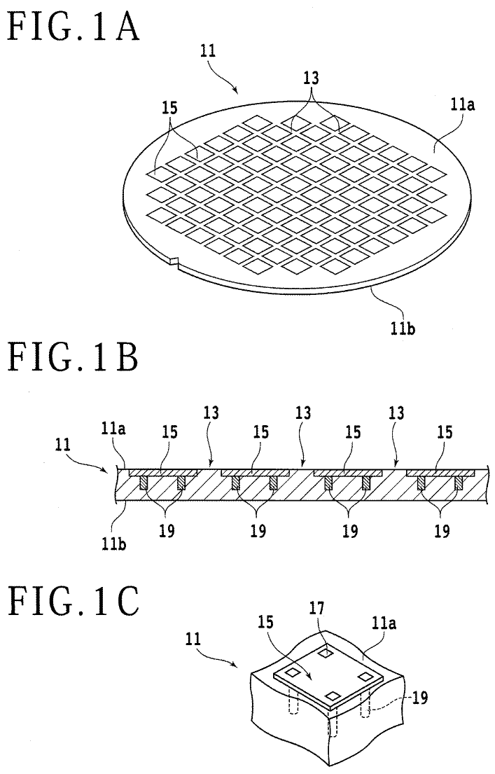

A preferred embodiment of the present invention will be described in detail below with reference to the accompanying drawings. First, a structural example of a workpiece that can be processed by a method of processing a workpiece according to the present embodiment will be described below. FIG. 1A illustrates the workpiece, denoted by 11, in perspective. FIG. 1B illustrates the workpiece 11 in fragmentary cross section.

The workpiece 11 is, for example, a disk-shaped wafer made of a semiconductor material such as monocrystalline silicon. The workpiece 11 has a face side, i.e., a first surface, 11a and a reverse side, i.e., a second surface 11b that lie generally parallel to each other. The workpiece 11 has a plurality of areas demarcated on the face side 11a by a grid of intersecting streets or projected dicing lines 13. A plurality of devices 15 such as integrated circuits (ICs), large-scale integration (LSI) circuits, light emitting diodes (LEDs), or microelectromechanical systems (MEMS) devices are constructed in the respective areas demarcated on the face side 11a by the streets 13. The workpiece 11 is not limited to any particular materials, shapes, structures, sizes, or the like. The workpiece 11 may be a substrate or a wafer made of semiconductors such as GaAs, InP, GaN, or SiC other than silicon, glass, ceramic, resin, metal, or the like, for example. The devices 15 are not limited to any particular kinds, quantities, shapes, structures, sizes, layouts, or the like.

FIG. 1C illustrates one of the devices 15 in perspective. The device 15 includes a plurality of electrodes 17 exposed on a face side of the device 15 for electric connection to other interconnects, electrodes, devices, or the like. Connection electrodes such as bumps may be disposed on face sides of the electrodes 17. A plurality of electrodes 19 such as vias or through electrodes are embedded in the workpiece 11 beneath the areas demarcated on the face side 11a by the streets 13. The electrodes 19 are shaped as columns extending thicknesswise through the workpiece 11 and have upper ends electrically connected to the respective electrodes 17 or the like. The electrodes 19 are not limited to any particular materials but may be made of any of electrically conductive materials including copper, tungsten, aluminum, and the like.

Each of the electrodes 19 extends from the device 15 toward the reverse side 11b of the workpiece 11 and has a length or height smaller than the thickness of the workpiece 11. Therefore, the electrodes 19 terminate short of, i.e., are not exposed on, the reverse side 11b of the workpiece 11 and are embedded in the workpiece 11. An insulating film, not illustrated, such as an oxide silicon film is interposed between the workpiece 11 and each of the electrodes 19, electrically insulating the workpiece 11 and the electrode 19 from each other. The assembly illustrated in FIG. 1C is manufactured as follows: An insulating film is deposited on inner wall surfaces of the workpiece 11 that define a plurality of columnar grooves in the workpiece 11 that are open at the face side 11a thereof. Then, the columnar grooves are filled with an electrically conductive material, providing electrodes 19 that are embedded in the workpiece 11. Thereafter, a device 15 including a semiconductor element, electrodes, interconnects, insulating films, and the like is constructed on the face side 11a of the workpiece 11 and is electrically connected to the electrodes 19.

When the workpiece 11 is thinned down by grinding the reverse side 11b thereof, the electrodes 19 have their lower ends exposed on the ground reverse side 11b. As a result, the electrodes 19 become through electrodes extending thicknesswise through the workpiece 11, and hence can electrically be connected to other interconnects, electrodes, devices, or the like. In this manner, the workpiece 11 with the through-silicon vias is produced.

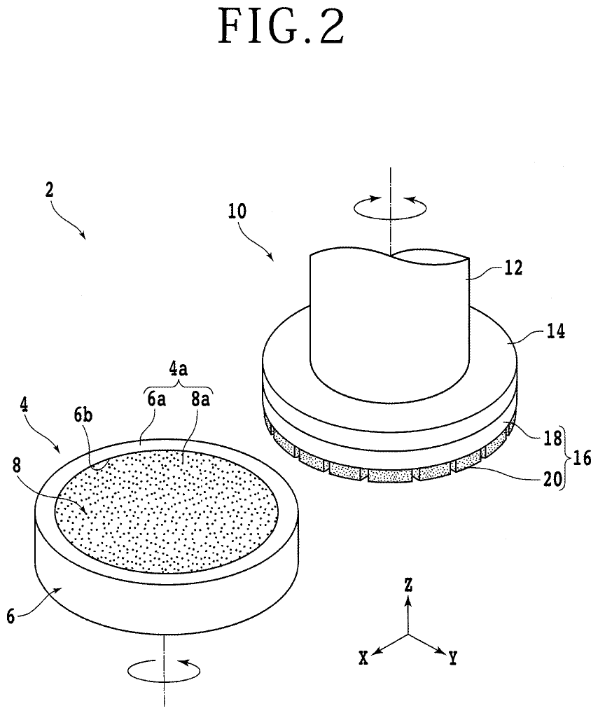

The workpiece 11 is ground by a grinding apparatus. FIG. 2 illustrates in perspective a grinding apparatus 2 for grinding the workpiece 11. In FIG. 2, the grinding apparatus 2 is illustrated in connection to an XYZ coordinate system having an X-axis, a Y-axis, and a Z-axis. The X-axis represents X-axis directions, i.e., first horizontal directions or forward and rearward directions, and the Y-axis represents Y-axis directions, i.e., second horizontal directions or leftward and rightward directions, the X-axis and the Y-axis extending perpendicularly to each other. The Z-axis represents Z-axis directions, i.e., processing feed directions, vertical directions, heightwise directions, or upward and downward directions. The Z-axis extends perpendicularly to the X-axis and the Y-axis. The grinding apparatus 2 includes a chuck table or holding table 4 for holding the workpiece 11 thereon and a grinding unit 10 for grinding the workpiece 11 held on the chuck table 4.

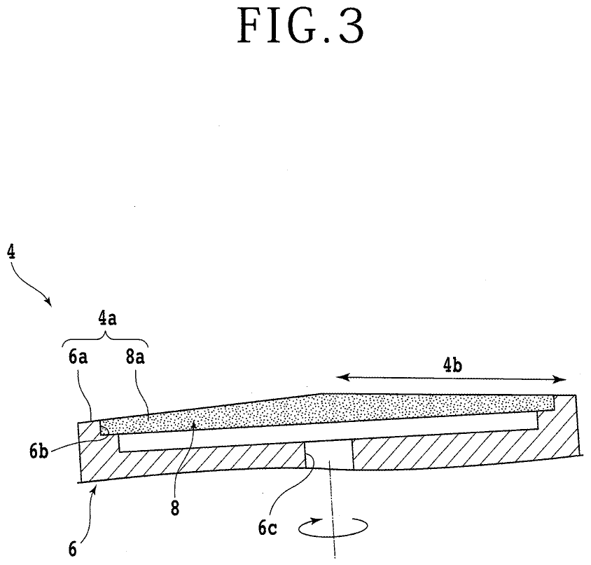

The chuck table 4 includes a cylindrical frame or main body 6 made of metal such as stainless steel (SUS), glass, ceramic, resin, or the like. The frame 6 has an upper surface 6a with a cylindrical recess 6b defined centrally therein. A disk-shaped holding member 8 made of a porous material such as porous ceramic is fitted in the recess 6b. As the holding member 8 is made of a porous material, it contains a multiplicity of pores or fluid passages extending between upper and lower end surfaces of the holding member 8. The upper end surface of the holding member 8 acts as a circular suction surface 8a for attracting the workpiece 11 under suction thereto when the workpiece 11 is held on the chuck table 4. The depth of the recess 6b and the thickness of the holding member 8 are generally the same as each other, so that the upper surface 6a of the frame 6 and the suction surface 8a of the holding member 8 lie substantially flush with each other. The upper surface 6a of the frame 6 and the suction surface 8a of the holding member 8 jointly provide a holding surface 4a of the chuck table 4. The suction surface 8a is fluidly connected to a suction source, not illustrated, such as an ejector through the pores of the holding member 8 and a fluid channel 6c (see FIG. 3) defined in the frame 6, and a fluid valve, not illustrated.

The chuck table 4 is operatively coupled to a moving unit, not illustrated, for moving the chuck table 4 in horizontal directions, i.e., directions in a horizontal XY plane defined by the X-axis and the Y-axis. The moving unit is a ball-screw-type moving mechanism or a turntable, for example. The chuck table 4 is also coupled to a rotary actuator, not illustrated, such as an electric motor for rotating the chuck table 4 in one direction about an axis perpendicular to the holding surface 4a.

FIG. 3 illustrates the chuck table 4 in cross section. The holding surface 4a of the chuck table 4 is of an upwardly protruding conical shape having an apex located at the center of the holding surface 4a. The holding surface 4a is slightly inclined downwardly in radially outward directions from the apex. The chuck table 4 is slightly tilted from the horizontal XY plane, i.e., the axis about which the chuck table 4 is rotatable is slightly tilted from the Z-axis, such that a holding area 4b of the holding surface 4a that extends from the center of the holding surface 4a radially outwardly to an outer circumferential edge of the holding surface 4a lies parallel to the horizontal XY plane. The axis about which the chuck table 4 is rotatable extends in directions perpendicular to the radial directions of the holding surface 4a and is slightly tilted from the vertical directions, i.e., the Z-axis. In FIG. 3, the tilt of the holding surface 4a is illustrated as exaggerated for illustrative purposes, but is actually smaller than illustrated. For example, if the holding surface 4a has a diameter in a range of approximately 290 to 310 mm, the difference between the height of the center of the holding surface 4a and the height of the outer circumferential edge of the holding surface 4a is set to a value in a range of approximately 20 to 40 μm.

As illustrated in FIG. 2, the grinding unit 10 is disposed above the chuck table 4. The grinding unit 10 includes a cylindrical spindle 12 extending along the Z-axis and a disk-shaped mount 14 made of metal or the like that is fixed to a lower distal end of the spindle 12. The spindle 12 has an upper proximal end coupled to a rotary actuator, not illustrated, such as an electric motor for rotating the spindle 12 bidirectionally, i.e., selectively in both directions, about its central axis.

An annular grinding wheel 16 for grinding the workpiece 11 on the chuck table 4 is mounted on a lower surface of the mount 14. The grinding wheel 16 is a machining tool detachably attached to the mount 14 and is fastened to the mount 14 by fasteners such as bolts, for example.

The grinding wheel 16 includes an annular wheel base 18 made of metal such as aluminum or stainless steel and having essentially the same diameter as the mount 14. The wheel base 18 has an upper surface secured to the lower surface of the mount 14. The grinding wheel 16 also includes a plurality of grindstones 20 fixed to a lower surface of the wheel base 18. Each of the grindstones 20 is made of abrasive grains made of diamond, cubic boron nitride (cBN), or the like and a binder or bonding material such as a metal bond, a resin bond, or a vitrified bond that binds the abrasive grains together. The grindstones 20, each shaped as a rectangular parallelepiped, for example, are arranged at equal spaced intervals in an annular array along an outer circumferential edge of the wheel base 18. The grindstones 20 are not limited to any particular materials, shapes, structures, sizes, or the like. The number and layout of the grindstones 20 may also be selected as desired.

The grinding unit 10 is operatively coupled to a ball-screw-type moving mechanism, not illustrated, for moving the grinding unit 10 along the Z-axis, i.e., for lifting and lowering the grinding unit 10. The grinding wheel 16 is rotatable about an axis generally parallel to the Z-axis by rotary power transmitted through the spindle 12 and the mount 14 from the rotary actuator coupled to the upper proximal end of the spindle 12. When the grinding wheel 16 is rotated about its axis, each of the grindstones 20 moves along an annular track, i.e., a movement path, generally parallel to the horizontal XY plane. While the grinding wheel 16 is being rotated, the ball-screw-type moving mechanism operatively coupled to the grinding unit 10 lowers the grinding unit 10 to bring the grindstones 20 into abrasive contact with the workpiece 11 held on the chuck table 4, thereby grinding the workpiece 11.

A grinding fluid supply passage, not illustrated, for supplying a grinding fluid such as pure water is provided in or near the grinding unit 10. When the grinding unit 10 grinds the workpiece 11, the grinding fluid is supplied through the grinding fluid supply passage to the workpiece 11 and the grindstones 20, thereby cooling the workpiece 11 and the grindstones 20 and washing away debris or swarf produced as the workpiece 11 is ground by the grindstones 20.

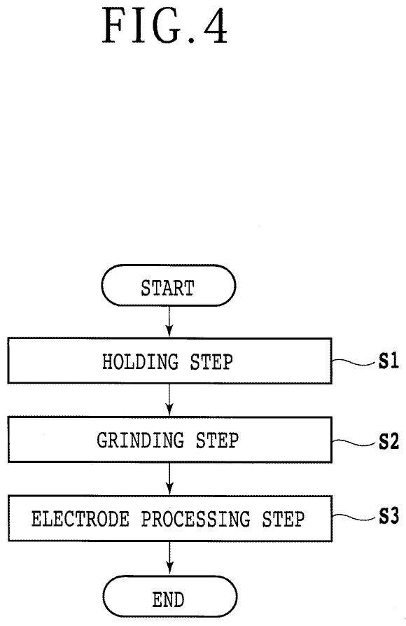

A specific example of the method of processing the workpiece 11 on the grinding apparatus 2 according to the present embodiment will be described below. FIG. 4 is a flowchart of the method of processing the workpiece 11. As illustrated in FIG. 4, the processing method includes a holding step S1, a grinding step S2, and an electrode processing step S3. By successively carrying out the holding step S1, the grinding step S2, and the electrode processing step S3, the electrodes 19 (see FIGS. 1B and 1C) are exposed on the reverse side 11b of the workpiece 11, and burrs developed on the electrodes 19 are removed.

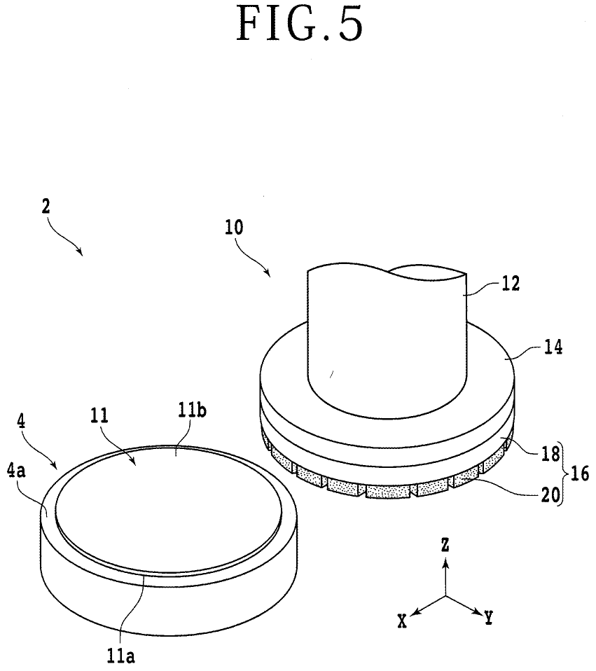

First, the face side 11a of the workpiece 11 is held on the chuck table 4 (holding step S1). FIG. 5 illustrates in perspective the grinding apparatus 2 in which the workpiece 11 is held on the chuck table 4 thereof.

The workpiece 11 is placed on the chuck table 4 with the face side 11a facing and contacting the holding surface 4a and with the reverse side 11b being exposed upwardly. At this time, the workpiece 11 is placed in such a position that the center of the workpiece 11 and the center of the holding surface 4a are positionally aligned with each other and the suction surface 8a (see FIG. 2) is covered in its entirety with the workpiece 11. Then, suction forces, i.e., a vacuum pressure, from the suction source are applied to the holding surface 4a, holding the workpiece 11 under suction on the chuck table 4. As described above, the holding surface 4a of the chuck table 4 is of an upwardly protruding conical shape (see FIG. 3). Therefore, when the workpiece 11 is held under suction on the chuck table 4, the workpiece 11 is slightly deformed into an upwardly protruding conical shape along the holding surface 4a.

A protective sheet for protecting the workpiece 11 may be affixed to the face side 11a of the workpiece 11 to cover and protect the devices 15 (see FIGS. 1A through 1C) on the face side 11a. The protective sheet may be a tape including a circular film-like base and an adhesive layer, i.e., a glue layer, affixed to the base. The base may be made of resin such as polyolefin, polyvinyl chloride, or polyethylene terephthalate. The adhesive layer may be made of an adhesive such as an epoxy-based adhesive, an acryl-based adhesive, or a rubber-based adhesive. If the protective sheet is affixed to the face side 11a of the workpiece 11, the workpiece 11 is held on the holding surface 4a of the chuck table 4 with the protective sheet interposed therebetween.

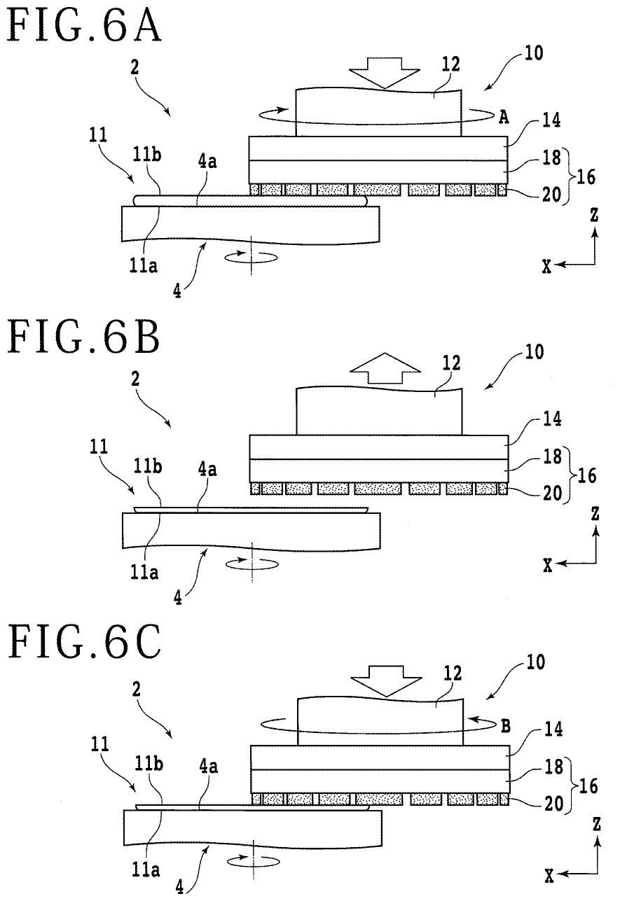

Then, while the grinding wheel 16 is being rotated about its axis in a direction referred to as a first direction, the grindstones 20 are brought into contact with the reverse side 11b of the workpiece 11 held on the chuck table 4, thereby grinding the workpiece 11 until the electrodes 19 (see FIGS. 1B and 1C) are exposed on the reverse side 11b (grinding step S2). FIG. 6A illustrates in side elevation the manner in which the grinding apparatus 2 is grinding the workpiece 11.

In the grinding step S2, first, a positional relation between the chuck table 4 and the grinding wheel 16 is adjusted. Specifically, the chuck table 4 is positioned below the grinding unit 10 such that the center of the workpiece 11 is aligned with the annular track to be followed by each of the grindstones 20. Then, the chuck table 4 and the grinding wheel 16 are rotated about their respective axes in respective predetermined directions at respective rotational speeds. For example, in the grinding step S2, the chuck table 4 and the grinding wheel 16 are rotated clockwise as viewed in plan. The grinding wheel 16 is thus rotated in the first direction, which is indicated by an arrow A in FIG. 6A. The rotational speed at which the chuck table 4 is rotated is set to a value in a range of 60 to 300 rpm, for example, and the rotational speed at which the grinding wheel 16 is rotated is set to a value in a range of 3000 to 6000 rpm, for example.

Next, while the chuck table 4 and the grinding wheel 16 are being rotated, the grinding unit 10 is lowered along the Z-axis to move the workpiece 11 and the grinding wheel 16 toward each other. At this time, the speed at which the grinding wheel 16 is lowered, i.e., the speed at which the chuck table 4, i.e., the workpiece 11, and the grinding wheel 16 are relatively moved along the Z-axis, represents a processing feed speed, i.e., a grinding feed speed. The processing feed speed is set to a value in a range of 0.1 to 1 μm/s, for example. The processing feed speed may be set to a suitable value depending on the kind and material of the workpiece 11, the material of the grindstones 20, the amount of material to be ground off the workpiece 11, i.e., the difference between the thicknesses of the workpiece 11 prior and subsequent to being ground, and the like. When the grinding wheel 16 is thus lowered, the rotating grindstones 20 are brought into abrasive contact with the reverse side 11b of the workpiece 11 held on the chuck table 4. The reverse side 11b of the workpiece 11 is now partly ground off, whereupon the workpiece 11 is thinned down.

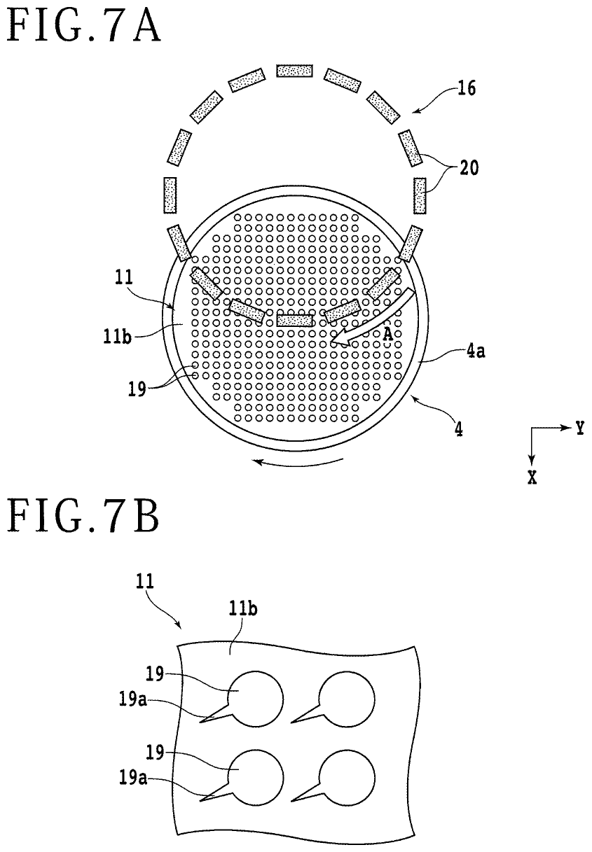

FIG. 7A illustrates in plan the workpiece 11 in the grinding step S2. In the grinding step S2, the grindstones 20 move in abrasive contact with a portion of the reverse side 11b of the workpiece 11 that is being supported on the holding area 4b (see FIG. 3) of the holding surface 4a of the chuck table 4 or a nearby area close thereto, arcuately grinding the reverse side 11b in the first direction indicated by an arrow A, i.e., a direction from an outer circumferential edge toward the center of the workpiece 11. Since the chuck table 4 is also rotated, the reverse side 11b of the workpiece 11 is ground in its entirety by the grindstones 20.

When the workpiece 11 has been ground to a predetermined thickness, the electrodes 19 embedded in the workpiece 11 are exposed on the reverse side 11b of the workpiece 11. As a result, the electrodes 19 become through electrodes extending thicknesswise through the workpiece 11, and hence can electrically be connected to other interconnects, electrodes, devices, or the like, as described above.

FIG. 7B illustrates in plan the electrodes 19 in the grinding step S2. When the workpiece 11 is ground until the electrodes 19 are exposed on the reverse side 11b of the workpiece 11, the grindstones 20 abrasively contact the electrodes 19 in a final phase of the grinding step S2. At this time, the grindstones 20 that are being rotated at a high speed are likely to elongate part of the electrodes 19 into hair-like burrs 19a along the direction in which the grindstones 20 are rotated, i.e., the direction indicated by the arrow A in FIG. 7A. The burrs 19a extend outwardly from outer circumferential edges of the electrodes 19. The burrs 19a are liable to cause the electrodes 19 to be shaped irregularly on the reverse side 11b of the workpiece 11 and develop problems such as short circuits between adjacent ones of the electrodes 19.

According to the present embodiment, after the grinding step S2, the grinding wheel 16 processes the electrodes 19 to reduce or remove the burrs 19a, thereby preventing the burrs 19a from remaining as they are on the workpiece 11.

Specifically, after the grinding step S2, the grinding unit 10 is lifted along the Z-axis, spacing the workpiece 11 and the grindstones 20 away from each other. FIG. 6B illustrates in side elevation the manner in which the grindstones 20 are spaced from the workpiece 11. While the workpiece 11 and the grindstones 20 are stay out of contact with each other, the chuck table 4 should preferably be kept in rotation in order to eliminate a period of time that would otherwise be required to rotate the chuck table 4 at a predetermined speed in the electrode processing step S3 that follows.

Then, while the grinding wheel 16 is being rotated in a second direction, the grindstones 20 are brought into contact with the electrodes 19 exposed on the reverse side 11b of the workpiece 11 held on the chuck table 4, thereby processing the electrodes 19 (electrode processing step S3). FIG. 6C illustrates in side elevation the manner in which the grinding apparatus 2 processes the electrodes 19.

In the electrode processing step S3, first, the spindle 12 is rotated in a direction opposite to the direction in which the spindle 12 has been rotated in the grinding step S2. The grinding wheel 16 is thus rotated in the second direction, which is indicated by an arrow B in FIG. 6C, that is opposite the first direction. Specifically, if the grinding wheel 16 is rotated clockwise as viewed in plan in the grinding step S2, then the grinding wheel 16 is rotated counterclockwise as viewed in plan in the electrode processing step S3. The rotational speed at which the chuck table 4 is rotated is set to a value in a range of 60 to 300 rpm, for example, and the rotational speed at which the grinding wheel 16 is rotated is set to a value in a range of 3000 to 6000 rpm, for example.

Next, while the chuck table 4 and the grinding wheel 16 are being rotated, the grinding unit 10 is lowered along the Z-axis to move the workpiece 11 and the grinding wheel 16 toward each other. When the grinding wheel 16 is thus lowered, the rotating grindstones 20 are brought into abrasive contact with the electrodes 19 exposed on the reverse side 11b of the workpiece 11 held on the chuck table 4, grinding off part of the electrodes 19 and the reverse side 11b of the workpiece 11.

With the workpiece 11 and the grindstones 20 spaced away from each other after the grinding step S2 (see FIG. 6B), no abrasive friction occurs between the workpiece 11 and the grindstones 20 prior to the electrode processing step S3, allowing the workpiece 11 and the grindstones 20 to be cooled. In the electrode processing step S3, therefore, the workpiece 11 is less likely to suffer a processing failure such as a surface burn. In the electrode processing step S3, when the grindstones 20 that have been spaced from the workpiece 11 are brought into abrasive contact with the workpiece 11 again, wear on the lower surfaces of the grindstones 20 is accelerated, putting the grindstones 20 into good conditions.

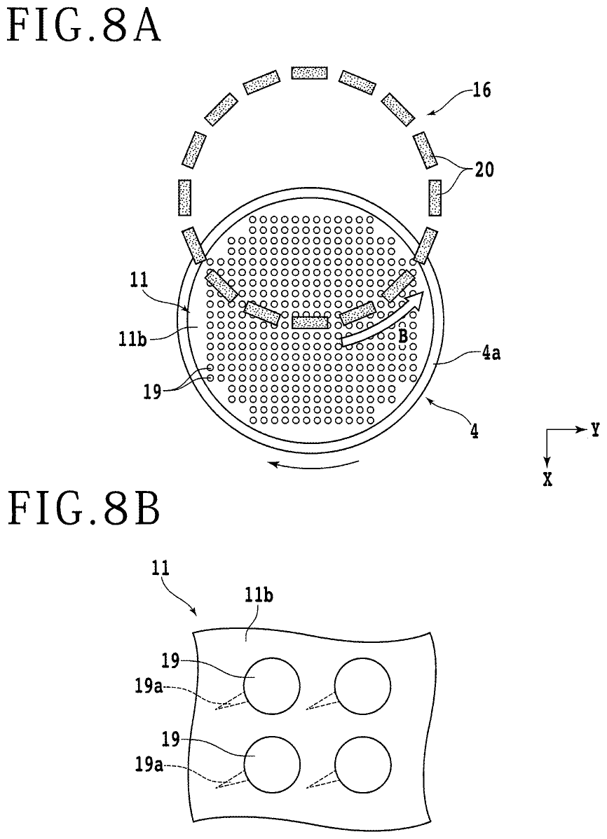

FIG. 8A illustrates in plan the workpiece 11 in the electrode processing step S3. In the electrode processing step S3, the grindstones 20 move in abrasive contact with a portion of the reverse side 11b of the workpiece 11 that is being supported on the holding area 4b (see FIG. 3) of the holding surface 4a of the chuck table 4 or a nearby area close thereto, arcuately grinding the reverse side 11b in the second direction indicated by an arrow B, i.e., a direction from the center toward the outer circumferential edge of the workpiece 11. The direction, i.e., the second direction, in which the grindstones 20 move with respect to the workpiece 11 in the electrode processing step S3 is opposite the direction, i.e., the first direction, in which the grindstones 20 move with respect to the workpiece 11 in the grinding step S2. Consequently, the grindstones 20 grind the exposed electrodes 19 in the direction opposite the direction in the grinding step S2. Since the chuck table 4 is also rotated, all the electrodes 19 exposed on the reverse side 11b of the workpiece 11 are ground in its entirety by the grindstones 20.

FIG. 8B illustrates in plan the electrodes 19 in the electrode processing step S3. When the grindstones 20 that are being rotated in the second direction are lowered into abrasive contact with the exposed electrodes 19, the grindstones 20 abrade the electrodes 19 along a direction opposite the direction in which the burrs 19a extend from the electrodes 19, i.e., a direction from distal to proximal ends of the burrs 19a. The grindstones 20 thus rub the burrs 19a back toward the center of the electrodes 19, thereby reducing or removing the burrs 19a.

The electrode processing step S3 is a step of reducing or removing the burrs 19a and does not primarily aim at thinning down the workpiece 11. Therefore, grinding conditions in the electrode processing step S3 can freely be established insofar as they can reduce or remove the burrs 19a. Specifically, the amount of material to be ground off the workpiece 11 in the electrode processing step S3 may be smaller than the amount of material to be ground off the workpiece 11 in the grinding step S2. In the electrode processing step S3, therefore, the workpiece 11 is prevented from being excessively ground or from developing new burrs. For example, the amount of material to be ground off the workpiece 11 in the electrode processing step S3 may be set to a value equal to or smaller than 10 μm, or preferably a value equal to or smaller than 5 μm. In addition, the processing feed speed, i.e., the speed at which the grinding wheel 16 is lowered, in the electrode processing step S3 may be lower than the processing feed speed in the grinding step S2. In the electrode processing step S3, therefore, the load imposed on the grindstones 20 may be reduced, allowing the burrs 19a to be removed with ease. For example, the processing feed speed in the electrode processing step S3 may be set to a value equal to or lower than 1 μm/s, or preferably a value equal to or smaller than 0.5 μm/s.

The processing operation performed on the workpiece 11 by the grinding apparatus 2 is controlled by a control unit, not illustrated, electrically connected to the grinding apparatus 2. The control unit is configured by a computer, for example, and includes an arithmetic processing device for performing arithmetic processing operations required to operate the grinding apparatus 2 and a storage device for storing various kinds of information such as data and programs used to operate the grinding apparatus 2. The arithmetic processing device includes a processor such as a central processing unit (CPU). The storage device includes memories such as a read only memory (ROM) and a random access memory (RAM). The storage device of the control unit stores programs descriptive of a sequence of operations of the working components of the grinding apparatus 2 that are required to successively perform the holding step S1, the grinding step S2, and the electrode processing step S3. For processing the workpiece 11, the processor reads the programs from the storage device, executes the programs, and successively outputs control signals to the working components of the grinding apparatus 2. In this manner, the grinding apparatus 2 is controlled to operate to automatically carry out the holding step S1, the grinding step S2, and the electrode processing step S3.

In the method of processing the workpiece 11 according to the present embodiment, as described above, after the grinding wheel 16 that is being rotated in the first direction has ground the workpiece 11 to expose the electrodes 19 on the reverse side 11b of the workpiece 11, the grinding wheel 16 that is being rotated in the second direction opposite the first direction processes the electrodes 19 to reduce or remove the burrs 19a extending from the electrodes 19, so that the burrs 19a are prevented from remaining as they are on the workpiece 11 after it has been ground.

The structure, method, and the like according to the above embodiment may be changed or modified appropriately without departing from the scope of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of processing a workpiece having electrodes embedded therein, comprising:
a holding step of holding a face side of the workpiece on a chuck table;
a grinding step of, after the holding step, bringing grindstones of a grinding wheel into contact with a reverse side of the workpiece held on the chuck table while rotating the grinding wheel in a first direction, thereby grinding the workpiece until the electrodes are exposed on the reverse side of the workpiece; and
an electrode processing step of, after the grinding step, processing the electrodes by bringing the grindstones into contact with the electrodes exposed on the reverse side of the workpiece held on the chuck table while rotating the grinding wheel in a second direction opposite the first direction.
